(19) United States
(12) Patent Application Publication
(10) Pub. No.: US 2009/0096014 A1
(43) Pub. Date: Apr. 16, 2009

(54) NONVOLATILE MEMORY DEVICES THAT INCLUDE AN INSULATING FILM WITH NANOCRYSTALS EMBEDDED THEREIN AND METHODS OF MANUFACTURING THE SAME

(75) Inventors: Sam-Jong Choi, Gyeonggi-do (KR); Kyoo-Chul Cho, Gyeonggi-do (KR); Jung-Sik Choi, Seongnam-si (KR); Hee-sung Kim, Gyeonggi-do (KR); Tae-Soo Kang, Gyeonggi-do (KR); Yoon-Hee Lee, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/137,109

(22) Filed: Jun. 11, 2008

(30) Foreign Application Priority Data
Jun. 11, 2007 (KR) 10-2007-0056875

(51) Int. Cl. H01L 29/792; H01L 21/31

(52) U.S. Cl. 257/324; 438/591; 257/E29.309; 257/E21.04

(57) ABSTRACT

A nonvolatile memory device includes a semiconductor substrate, a charge-trap structure disposed on the semiconductor substrate, which includes an insulating film and a plurality of carbon nanocrystals embedded in the insulating film, and a gate disposed on the charge-trap structure. The nonvolatile memory device may exhibit memory hysteresis characteristics with improved reliability.

### CROSS REFERENCE TO RELATED APPLICATION

This application claims priority from Korean Patent Application No. 10-2007-0056875 filed on Jun. 11, 2007 in the Korean Intellectual Property Office, the disclosure of which is incorporated herein by reference in its entirety.

### FIELD OF THE INVENTION

The present invention relates to nonvolatile memory devices, and, more particularly, to nonvolatile memory devices including nanocrystals in a charge-trap structure and methods of manufacturing the same.

### BACKGROUND OF THE INVENTION

Nonvolatile memory devices can retain data even if power is lost and are widely used in information communication apparatus, such as digital cameras, mobile phones, PDAs, and MP3 players. However, as devices are provided with many functions, nonvolatile memory devices may be required that provide actuation at low power, provide high-speed operation, provide high reliability, provide large storage, and provide high integration.

To satisfy these demands, a variety of experiments, such as using nanocrystal as an electrical charge trap node instead of a floating gate, have been conducted. However, in nanocrystal nonvolatile memory devices manufactured by conventional methods, memory hysteresis characteristics may fail to meet a desired standard and/or the stability of the nanocrystal may not be ensured for subsequent processing, which may reduce reliability.

### SUMMARY OF THE INVENTION

According to some embodiments of the present invention, there is provided a nonvolatile memory device that includes a semiconductor substrate and a charge-trap structure disposed on the semiconductor substrate. The charge-trap structure includes an insulating film and a plurality of carbon nanocrystals embedded in the insulating film. A gate is disposed on the charge-trap structure.

According to other embodiments of the invention, there is provided a method of manufacturing a nonvolatile memory device including forming a charge-trap structure on a semiconductor substrate that includes an insulating film and a plurality of carbon nanocrystals embedded in the insulating film, and forming a gate on the charge-trap structure.

According to still other embodiments of the present invention, there is provided a stack-typed nonvolatile memory device that includes a first nonvolatile memory device layer including a first active region, a first charge-trap structure disposed on the first active region, and a first gate formed on the first charge-trap structure, and a second nonvolatile memory device layer stacked on the first nonvolatile memory device layer including a second active region, a second charge-trap structure disposed on the second active region, and a second gate formed on the second nonvolatile memory device layer. At least one of the first charge-trap structure and the second charge-trap structure includes an insulating film and a plurality of nanocrystals embedded in the insulating film.

Nonvolatile memory devices, according to some embodiments of the present invention, may exhibit memory hysteresis characteristics with improved reliability.

### BRIEF DESCRIPTION OF THE DRAWINGS

The above and other features and advantages of the present invention will become apparent by describing in detail embodiments thereof with reference to the attached drawings in which:

FIG. 1 is a cross-sectional view of a nonvolatile memory device according to some embodiments of the invention;

FIG. 2 is an enlarged cross-sectional view of a charge-trap structure of the nonvolatile memory device shown in FIG. 1;

FIG. 3 is a cross-sectional view showing a modification of the charge-trap structure shown in FIG. 2;

FIG. 4 is a cross-sectional view of a nonvolatile memory device according to other embodiments of the invention;

FIG. 5 is an enlarged cross-sectional view of a charge-trap structure of the nonvolatile memory device shown in FIG. 4;

FIGS. 6A to 6D are cross-sectional views showing a variety of modifications of the charge-trap structure shown in FIG. 5;

FIGS. 7 and 8 are cross-sectional views illustrating methods of manufacturing a nonvolatile memory device according to some embodiments of the invention;

FIGS. 9 to 11 are cross-sectional views illustrating methods of manufacturing a nonvolatile memory device according to other embodiments of the invention;

FIG. 12A is a TEM photograph after injecting ions for forming a carbon nanocrystal in an insulating film according to some embodiments of the invention;

FIG. 12B is a TEM photograph after forming a carbon nanocrystal in an insulating film according to some embodiments of the invention;

FIG. 12C is a TEM photograph with carbon nanocrystal enlarged in an insulating film according to some embodiments of the invention;

FIG. 13 is a TEM photograph showing the cross-section of a nonvolatile memory device according to some embodiments of the invention;

FIG. 14 is a graph showing a capacitance (C)-to-voltage (V) curve for a nonvolatile memory device according to some embodiments of the invention;

FIG. 15 is a cross-sectional view of a stack-typed nonvolatile memory device according to some embodiments of the invention;

FIGS. 16A and 16B are cross-sectional views of a transistor including nanocrystals that is applicable to the memory cell transistor shown in FIG. 15;

FIG. 17 is a cross-sectional view of a transistor not including nanocrystals that is applicable to the memory cell transistor shown in FIG. 15; and

FIG. 18 is a cross-sectional view of a transistor that is applicable to the string selection transistor and the grounding selection transistor shown in FIG. 15.

### DETAILED DESCRIPTION OF EMBODIMENTS

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout the description of the figures.

It will be understood that when an element is referred to as being “on” another element, it can be directly on the other element or intervening elements may be present. In contrast, when an element is referred to as being “directly on” another element, there are no intervening elements present. It will be understood that when an element is referred to as being “connected” or “coupled” to another element, it can be directly connected or coupled to the other element or intervening elements may be present. In contrast, when an element is referred to as being “directly connected or coupled” to another element, there are no intervening elements present. Furthermore, “connected” or “coupled” as used herein may include wirelessly connected or coupled. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another. For example, a first layer could be termed a second layer, and, similarly, a second layer could be termed a first layer without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to other elements as illustrated in the Figures. It will be understood that relative terms are intended to encompass different orientations of the device in addition to the orientation depicted in the Figures. For example, if the device in one of the figures were turned over, elements described as being on the “lower” side of other elements would then be oriented on “upper” sides of the other elements. The exemplary term “lower”, can therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

In the description, a term “substrate” used herein may include a structure based on a semiconductor, having a semiconductor surface exposed. It should be understood that such a structure may contain silicon, silicon on insulator, silicon on sapphire, doped or undoped silicon, epitaxial layer supported by a semiconductor substrate, or another structure of a semiconductor. And, the semiconductor may be silicon-germanium, germanium, or germanium arsenide, not limited to silicon. In addition, the substrate described hereinafter may be one in which regions, conductive layers, insulation layers, their patterns, and/or junctions are formed.

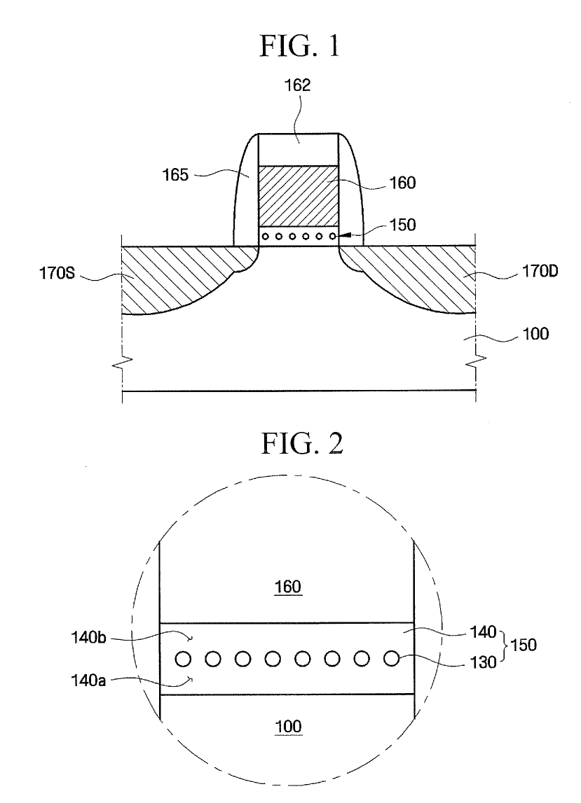

FIG. 1 is a cross-sectional view of a nonvolatile memory device according to some embodiments of the present invention. Referring to FIG. 1, a nonvolatile memory device includes a semiconductor substrate 100, a charge-trap structure 150 formed on the semiconductor substrate 100, and a gate 160 formed on the charge-trap structure 150.

The semiconductor substrate 100 includes an active region that is defined by an isolation region (not shown). A source 170S and a drain 170D are spaced apart from each other in the active region. As shown in FIG. 1, the source 170S and the drain 170D are an LDD type, but may be formed of only low concentration dopant regions if the punch-through of the memory cell becomes a problem.

The active region includes a channel defined between the source 170S and the drain 170D. The charge-trap structure 150 is disposed on the channel. The charge-trap structure 150 stores data by trapping electrical charges injected from the semiconductor substrate 100. The charge-trap structure 150 will be described in detail below.

The gate 160 is formed on the charge-trap structure 150. The gate 160 may substantially function as a control gate. The gate 160 may be a single film or a multilayered film. A doped polycrystal silicon film, a metal silicide film, and/or a metal film may be used as the single film in accordance with various embodiments of the present invention. A metal film/metal barrier film, a metal film/doped polycrystal silicon film, a metal silicide film/metal silicide film, and/or a metal silicide film/doped polycrystal silicon film may be used as the multilayered film in accordance with various embodiments of the present invention. A metallic material for the single film or the multilayered film may include, but is not limited to Al, W, Ni, Co, Ru—Ta, Ni—Ti, Ti—Al—N, Zr, Hf, Ti, Ta, Mo, Ta—Pt, Ta—Ti, and/or W—Ti. The metal barrier material may include, but is not limited to WN, TiN, TaN, TaCN, and/or MoN, and the metal silicide may include, but is not limited to WSiₓ, CoSiₓ, and/or NiSiₓ. Various materials may be used for the gate in accordance with some embodiments of the present invention.

A capping film 162 may be formed on the gate 160 and a side spacer 165 may be formed on the sides of the gate 160. When the source 170S and drain 170D are not an LDD type, but are formed of only a low concentration dopant region, the side spacer 165 may be an oxide film formed by oxidation of the gate 160. The capping film 162 and/or the side spacer 165 may be removed or omitted.

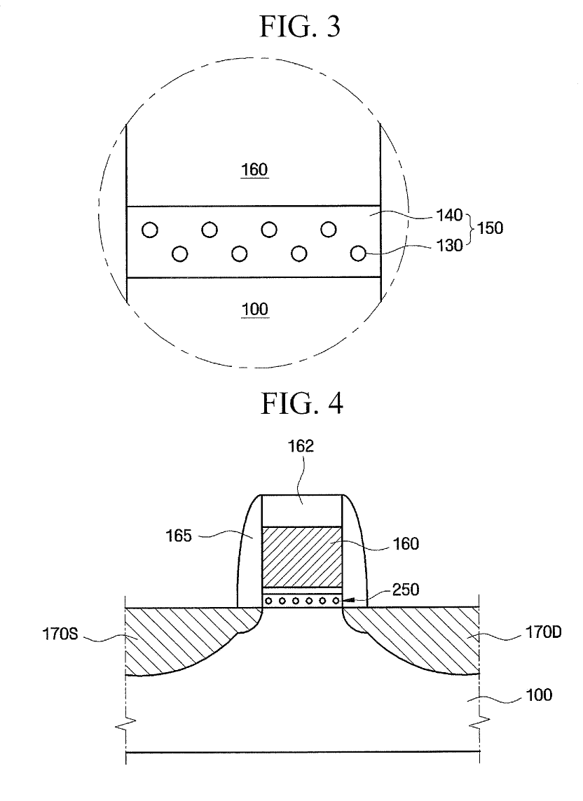

FIG. 2 is an enlarged cross-sectional view of the charge-trap structure of the nonvolatile memory device shown in FIG. 1. FIG. 3 is a cross-sectional view showing a modification of the charge-trap structure shown in FIG. 2 according to some embodiments of the present invention.

The charge-trap structure 150, as shown in FIG. 2, includes an insulating film 140 and a plurality of nanocrystals 130 embedded in the insulating film 140. The nanocrystals 130 trap electrical charges injected into the insulating film 140. The nanocrystals 130 may be about 1 to 15 m in diameter, and may include dot-shaped nanocrystals having a diameter in the range of about 3 to 7 nm.

It may be desirable to space the nanocrystals 130 from each other to reduce or prevent disturbance caused by lateral diffusion of the electrical charges. For this reason, the distance between the nanocrystals 130 may be about 3 to 7 nm. However, the size and distance of the nanocrystals 130 are not limited to the above range.

The nanocrystals 130 may be made of group IV elements, and may comprise carbon nanocrystals, germanium nanocrystals, and/or silicon nanocrystals. Properties for each of the nanocrystals 130 are shown in Table 1.

TABLE 1
Properties of some nanocrystals

| | | Carbon | Germanium | Silicon |
|---|---|---|---|---|
| Temperature for forming | | 1000-1250 | 700-950 | 950-1100 |
| nanocrystal (° C.) | | | | |
| Melting Point (° C.) | | 3547 | 940 | 1412 |
| Atomic Weight | | 12.01 | 72.59 | 28.08 |
| Mobility | Electron | 2200 | 3900 | 1500 |
| (cm²/V-s) | Hole | 1600 | 1900 | 450 |

As seen from Table 1, difference in the temperature for forming nanocrystals of carbon from germanium and silicon is not large, whereas the melting point is considerably high. High melting point of an element may provide an advantage of ensuring stability even though a following high-temperature process is performed after forming the nanocrystals 130. That is, even though the nanocrystals 130 are formed in the insulating film 140, when the temperature for a following process is higher than the melting point of the element, crystallization may be broken due to melting of the nanocrystals 130. However, a high melting point of an element reduces the probability of crystallization break. That is, when the melting point of an element is high, the range of temperature that may be used in following processes increases.

Further, because the atomic weight of carbon is considerably less than germanium and silicon, damage to the insulating film 140 during injection of ions for forming the nanocrystals 130 may be relatively small and shallow implantation is relatively easy. In addition, carbon is generally better in mobility of electrons and/or holes than silicon, so it has characteristics that are suitable for the nanocrystals 130 for trapping electrical charge.

Furthermore, a relatively high temperature of about 1000 to 1250° C. for forming carbon nanocrystals may have the advantage of curing defects inside the insulating film 140 that may be caused by injection of carbon ions. Accordingly, it may be possible to reduce or prevent electrical charge trap due to undesired defects, or electric current leakage.

Therefore, in some embodiments of the invention that will be described hereafter, carbon nanocrystals are used as nanocrystals contained in a charge-trap structure. It will be understood, however, that the nanocrystals contained in the charge-trap structure are not limited to carbon nanocrystals, in accordance with various embodiments of the present invention.

The nanocrystals 130 are spaced from the lower semiconductor substrate 100 (e.g., the channel of active region) and the upper gate 160. Accordingly, the nanocrystals 130 are electrically floated from the lower semiconductor substrate 100 and the upper gate 160.

The lower insulating film region 140a between the nanocrystals 130 and the lower semiconductor substrate 100 electrically insulates the nanocrystals 130 from the semiconductor substrate 100 and functions as passage for electrons that are injected into or removed from the semiconductor substrate 100. That is, the lower insulating film region 140a functions as a tunneling insulating film. The thickness of the lower insulating film region 140a (i.e., the distance between the nanocrystals 130 and the semiconductor substrate 100) may be set such that it allows easy tunneling of electrons when a predetermined program voltage is applied, for example about 9 nm or less.

The upper insulating film region 140b between the nanocrystals 130 and the upper gate 160 electrically insulates the nanocrystals 130 from the upper gate 160, transmits a voltage applied to the upper gate 160 to the nanocrystals 130 through coupling, and reduces or prevents electrical charges trapped in the nanocrystals 130 from being discharged to the gate 160. That is, the upper insulating film region 140b functions as a coupling and blocking insulating film.

Therefore the insulating film 140 may be made from a material that satisfies some or all of the characteristics for a tunneling insulating film and coupling and blocking insulating film.

For example, the insulating film 140 may be formed of a film having an energy band gap more than about 5 eV, so that tunneling of electrons is not easy in the initial state. Further, when the insulating film 140 is formed of a film having a dielectric constant of more than about 7, as compared with an oxide film or nitride film, it has electrically about the same ETO (Equivalent Oxide film Thickness) and physically large thickness such that tunneling generally does not occur. Therefore, it may be advantageous for forming a highly integrated component. Further, when the insulating film 140 is formed of a film that has a denser layer than a silicon oxide film, it may be possible to reduce or minimize vertical and horizontal diffusion in injection of ions for forming the nanocrystals. Accordingly, even though processes may be performed with a plurality of wafers simultaneously inserted in a process tube, it may be possible to reduce or minimize cross-contamination where adjacent wafers are contaminated by ions that diffuse out of the wafer.

Considering the above-mentioned conditions, the insulating film 140 may be formed of a single metal oxide of group III metal (e.g. Sc, Y, La), group IV metal (e.g. Zr, Hf, Ti), and/or group XIII metal (e.g. Al), or an alloy thereof. These materials may be expressed as AₓO_{y}, AₓB₁₋ₓO_{y}, AₓO_{y}N_{z} or AₓB₁₋ₓO_{y}N_{z} (‘A’ and ‘B’ are different substances selected from a group of Ti, Zr, Hf, Sc, Y, La and Al). Al₂O₃ (dielectric constant of about 9 and energy band gap of about 8.7 eV) is an example material that may be used for the insulating film 140 in accordance with some embodiments of the invention. HfO₂ (dielectric constant of about 25 and energy band gap of about 5.7 eV) or ZrO₂ (dielectric constant of about 25 and energy band gap of about 7.8 eV) may also be an example satisfying the above conditions for use as the insulating film 140.

Forming the insulating film 140 as thin as possible, for example, to about 30 nm or less, may have the advantage of forming a single layer of the nanocrystal 130. The single layer of nanocrystal 130, as shown in FIG. 2, implies that the centers of the nanocrystals 130 are substantially arranged in a plane (a straight line in the cross-sectional view) that is parallel with the surface of the semiconductor substrate 100 in a single layer.

In contrast, other embodiments of the invention, as shown in FIG. 3 by way of example, include an example in which nanocrystals are not arranged substantially in a plane. This is obtained by intentionally arranging the nanocrystals 130 in a multilayered structure for storing multi-level data, or the nanocrystals 130 may be formed irregularly according to differences in injection depth, the amount of diffusion, etc. It should be understood that the above examples illustrate various embodiments of the present invention in which the nanocrystals 130 are embedded in the insulating film 140.

Nonvolatile memory devices according to the above embodiments of the invention may program and/or erase data from the nanocrystals 130 of the charge-trap structure 150 by controlling the voltage that is applied to the gate 160, semiconductor substrate 100, source 170S, and drain 170D.

In detail, as for programming data, when a predetermined amount of program voltage is applied to the gate 160 and a grounding voltage is applied to the semiconductor substrate 100, electrons are trapped to the nanocrystals 130 through the lower insulating film region 140a by FN tunneling. Alternatively, when a predetermined amount of voltage is applied to the gate 160, a high voltage that is substantially similar to the voltage applied to the gate 160 is applied to the source 170S, and a grounding voltage is applied to the drain 170D, electrons are trapped to the nanocrystals 130 through the lower insulating film region 140a by hot electron injection.

As for erasing data, when the ground voltage is applied to the gate 160 and the erase voltage is applied to the semiconductor substrate 100, the electrons trapped in the nanocrystals 130 are discharged to the semiconductor substrate 100 by FN tunneling and are erased. Hot electron injection may also be used for erasing.

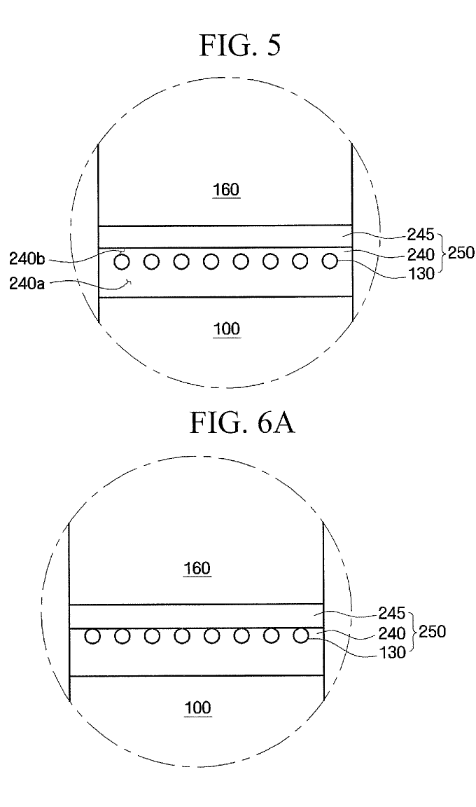

FIG. 4 is a cross-sectional view of a nonvolatile memory device according to some embodiments of the invention. FIG. 5 is an enlarged cross-sectional view illustrating the charge-trap structure of the nonvolatile memory device shown in FIG. 4. In the description of these embodiments, differences from the embodiments of FIGS. 1 and 2 are emphasized to avoid repetition.

Referring to FIGS. 4 and 5, in a nonvolatile memory device according to some embodiments of the present invention, unlike the embodiments shown in FIGS. 1 to 3, the insulating film is formed of a multilayered film, not a single film.

In detail, a charge-trap structure 250 includes a first insulating film 240 and a second insulating film 245 formed on the first insulating film 240. The nanocrystals 130 are embedded in the first insulating film 240.

The first insulating film 240 may be made of the same material as the insulating film 140 described in relation to FIGS. 1 to 3.

The second insulating film 245 may function as a capping film that effectively reduces or blocks ions for forming the nanocrystals, for example, carbon ions injected in the first insulating film 240 from diffusing outside. Therefore, the nanocrystals 130 can be effectively embedded at desired positions inside the first insulating film 240 due to the second insulating film 245.

The second insulating film 245 may be made of a material having a relatively high dielectric constant, e.g., a dielectric constant of more than about 4. That is, when capacitance is increased by forming the second insulating film 245 of a material having a relatively high dielectric constant of more than about 4, the nonvolatile memory device may have relatively high-speed operation and relatively large capacitance characteristics.

The second insulating film 245 may be made of AₓO_{y}, AₓB₁₋ₓO_{y}, AₓO_{y}N_{z}, AₓB₁₋ₓO_{y}N_{z} (where, ‘A’ and ‘B’ are different substances selected from the group of Sc, Y, La, Ti, Zr, Hf, and Al) or SiN in accordance with various embodiments of the present invention.

The second insulating film 245 may be formed of any material that is the same as or different from the first insulating film 240, but when it is formed of the same material that has a relatively high dielectric constant as the first insulating film 240, large capacitance and high-speed operation may be achieved and processes may be reduced without any specific manufacturing equipment. Accordingly, the second insulating film 245 may be made of Al₂O₃, HfO₂, or ZrO₂.

To increase or maximize the capacitance for high-speed operation, the second insulating film 245 may be formed to a thickness of about 10 nm or less. The total thickness of the insulating films 240, 245, as shown in FIGS. 1 to 3, may be about 30 nm or less. For these conditions, the first insulating film 240 may be formed to have a thickness of about 20 nm or less.

The nanocrystals 130, as shown in FIGS. 1 and 2, are spaced from the lower semiconductor substrate 100 and the upper gate 160. The first lower insulating film 240a disposed between the nanocrystals 130 and semiconductor substrate 100 may function as a tunneling insulating film, similar to the lower insulating film region 140a of FIG. 2. The first upper insulating film 240b and second insulating film 245, corresponding to the upper insulating film 140a of FIG. 2, disposed between the nanocrystals 130 and gate 160, may function together as a coupling and blocking insulating film.

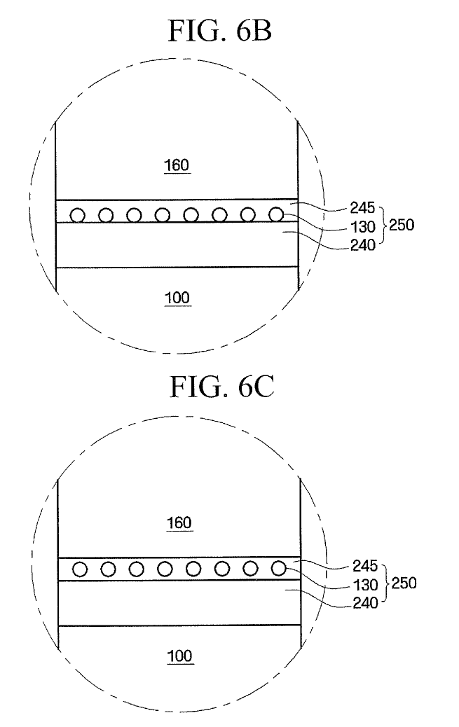

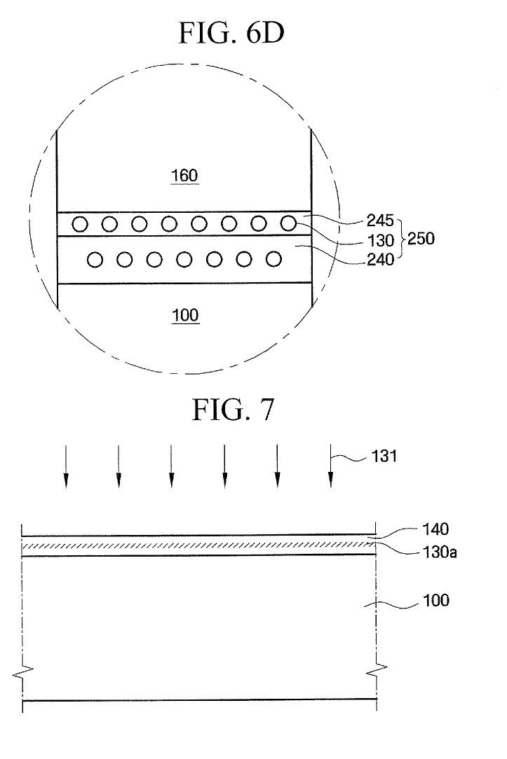

FIGS. 6A to 6D show a variety of modifications for the positions of the nanocrystals of FIG. 5. That is, the nanocrystals 130 are positioned in the first insulating film 240 as shown in FIG. 6A, depending on the ion injection depth or the amount of diffusion, but may be in contact with the interface of the first insulating film 240 and second insulating film 245. Further, as shown in FIG. 6B, the nanocrystals 130 may be positioned at the interface of the first insulating film 240 and second insulating film 245 inside the second insulating film 245 by diffusion to the second insulating film 245, or as shown in FIG. 6C, in the second insulating film 245. In addition, the nanocrystals 130, as shown in FIG. 6D, may be positioned in the first insulating film 240 and the second insulating film 245 at the same time. These variations are just examples of possible embodiments of the present invention, and may be changed in a variety of ways by combining the nanocrystals 130 in an irregular arrangement as described with reference to FIG. 3.

Methods of manufacturing the above nonvolatile memory devices, according to some embodiments of the present invention, are described hereafter. In the following embodiments, the components, dimensions, materials, etc. that are the same as or inferred from the embodiments of FIGS. 1 to 6D are simply described or not described.

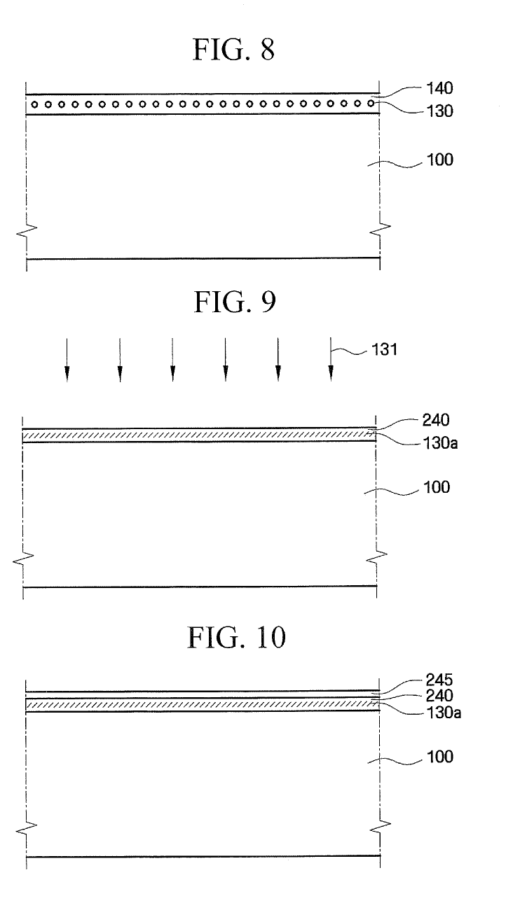

FIGS. 7 and 8 are cross-sectional views illustrating methods of manufacturing nonvolatile memory devices according to some embodiments of the invention, such as the nonvolatile memory devices discussed above with respect to FIG. 1.

Referring to FIG. 7, the insulating film 140 is formed on the semiconductor substrate 100. The insulating film 140 is formed by atomic layer vapor deposition or PECVD (Plasma Enhance Chemical Vapor Deposition). Selectable materials and thicknesses for the insulating film 140 are the same as those described above with reference to FIGS. 1 and 2.

Subsequently, ions 130a for forming the nanocrystals are injected into the insulating film 140 (131). When the ions 130a for forming the nanocrystals are carbon ions, damage to the insulating film 140 in the ion injection 131 may be relatively small with shallow injection; therefore, it may be possible to reduce or minimize the thickness of the insulating film 140. When the ions 130a for forming the nanocrystals are carbon ions, the ion injection 131 may be applied at an ion injection energy of about 30 to 80 KeV and an ion injection dose of about 1×10¹⁶/cm² or less.

Referring to FIG. 8, annealing is applied to the resultant structure. The annealing may be rapid thermal annealing in an inactive gas atmosphere, such as a nitride gas atmosphere. The annealing may be applied at a temperature where the ions 130a can be crystallized, which may reduce or minimize diffusion of the ions 130a outside of the insulating film 140. When the injected ions 130a are carbon ions, the temperature meeting the above conditions may be in the range of about 1000 to 1300° C., and the annealing may be applied for about 5 to 60 minutes.

In some embodiments of the invention, the annealing may be applied by a multi-step annealing process. Multi-step annealing includes two or more annealing processes at different temperatures.

As a result of the annealing, the ions 130a for forming the nanocrystals in the insulating film 140 are crystallized into the nanocrystals 130 as shown in FIG. 8. Further, even though the ion injection 131 may partially cause defects inside the insulating film 140, they may be cured by the above annealing. Therefore, it may be possible to reduce or prevent undesired electrical charge trap or current leakage. Further, the insulating film 140 may be crystallized by annealing, and, as a result, current leakage through the insulating film 140 is further reduced or prevented. In contrast, the nanocrystals 130 may be formed in the pattern shown in FIG. 3 depending on ion injection conditions or annealing conditions.

Subsequently, through common vapor deposition and photo-etching, as shown in FIG. 1, the gate 160 is formed on the charge-trap structure 150, the capping film 162 on the gate 160, and the side spacer 165 on the sides of the gate 160. Further, the source 170S and drain 170D are formed by injecting dopant ions into the semiconductor substrate 100. In FIG. 1, the charge-trap structure 150 is patterned with the gate 160.

Methods according to some embodiments of the present invention may include additionally annealing the insulating film 140 before the ions 130a for forming the nanocrystals. When annealing of the insulating film 140 is included, the insulating film 140 is crystallized so that not only current leakage is reduced or prevented, but the ions 130a for forming the nanocrystals that are injected in the following process are prevented from diffusing or the diffusion is lessened. Accordingly, the nanocrystal 130 is formed in a single layer. The additional annealing of the insulating film 140 may be applied in rapid thermal annealing under inactive gas atmosphere, such as, for example, a nitride gas atmosphere. When the insulating film 140 is made of Al₂O₃, the additional annealing of the insulating film 140 may be applied at about 950° C. or more for about 5 to 30 minutes.

FIGS. 9 to 11 are cross-sectional views illustrating methods of manufacturing a nonvolatile memory device according to some embodiments of the invention, such as the nonvolatile memory devices discussed above with respect to FIG. 4.

Referring to FIG. 9, the first insulating film 240 is formed on the semiconductor substrate 100. The first insulating film 240 may be formed by atomic layer vapor deposition or PECVD (Plasma Enhance Chemical Vapor Deposition). Selectable materials and thicknesses for the first insulating film 240 are the same as those described above with reference to FIGS. 4 and 5.

Subsequently, the ions 130a for forming nanocrystals are injected into the first insulating film 240 (131). This operation is substantially the same as that described above with reference to FIG. 7.

Referring to FIG. 10, the second insulating film 245 is formed on the first insulating film 240 containing the ions 130a for forming the nanocrystal. The second insulating film 245 may be formed by atomic layer vapor deposition or PECVD (Plasma Enhance Chemical Vapor Deposition). Selectable materials and thicknesses for the second insulating film 245 are the same as those described above with reference to FIGS. 4 and 5.

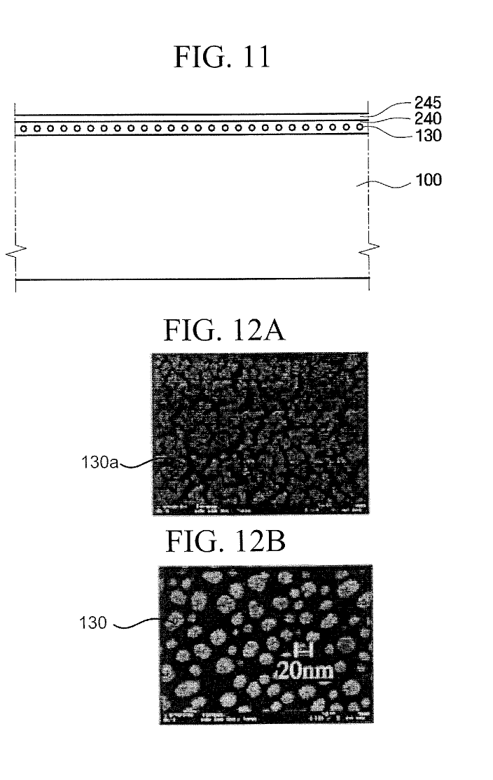

Referring to FIG. 11, the resultant structure is annealed. The annealing is substantially the same as that described above with reference to FIG. 8.

As a result of the annealing, the ions 130a for forming the nanocrystal in the first insulating film 240 are crystallized into the nanocrystal 130 as shown in FIG. 11. Further, even though the ion injection 131 may partially cause defects inside the first insulating film 240, they can be cured by the annealing. Accordingly, it may be possible to reduce or prevent undesired current leakage or charge trapping. Further, in the above annealing process, the first insulating film 240 and/or the second insulating film 245 may be crystallized. As a result, current leakage through the first insulating film 240 and/or the second insulating film 245 can be reduced or prevented.

The nanocrystals 130 may be formed in the patterns shown in FIGS. 6A to 6D, depending on ion injection conditions or annealing conditions. In contrast, according to some embodiments of the present invention, the annealing may be performed before the second insulating film 245 is formed.

Subsequently, through common vapor deposition and photo-etching, as shown in FIG. 4, the gate 160 is formed on the charge-trap structure 250, the capping film 162 on the gate 160, and the side spacer 165 on the sides of the gate 160. Further, the source 170S and drain 170D are formed by injecting dopant ions into the semiconductor substrate 100. In FIG. 4, the charge-trap structure 250 is patterned with the gate 160.

Further, similar to the embodiments of FIGS. 7 and 8, the methods according to some embodiments of the present invention may further include annealing the first insulating film 240 before injecting ions 130a for forming the nanocrystals. The additional annealing of the first insulating film 240 is performed in substantially the same way as the additional annealing of the insulating film 140.

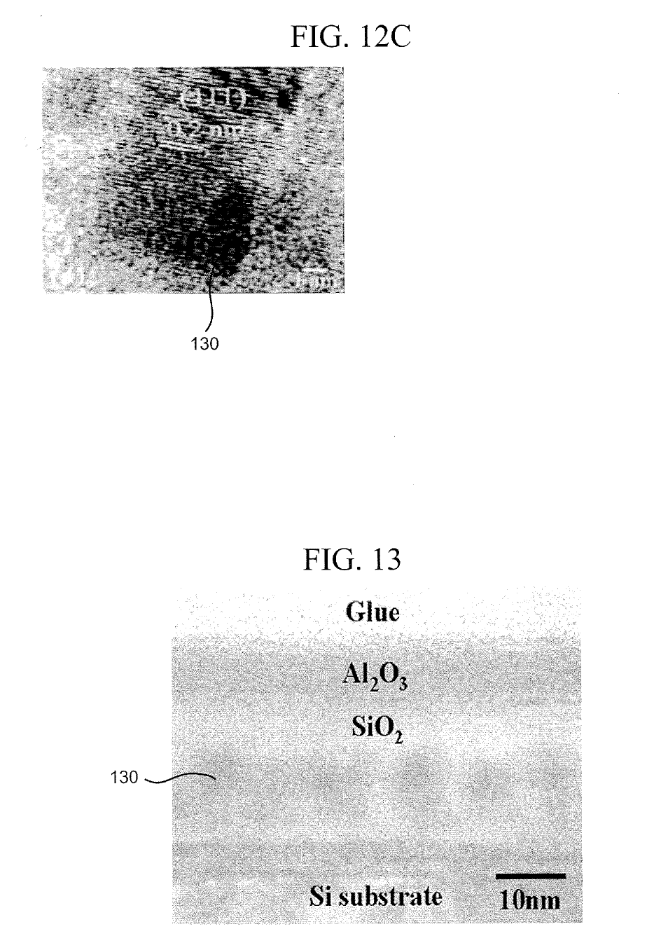

FIGS. 12A to 13 are TEM photographs illustrating that nanocrystals can be formed by methods according to some embodiments of the invention. In FIGS. 12A to 13 carbon nanocrystals are used.

FIG. 12A is a TEM photograph after injecting ions for forming carbon nanocrystal in an insulating film according to some embodiments of the invention. FIG. 12A illustrates injected carbon ions 130a that are not yet crystallized (before annealing).

FIG. 12B is a TEM photograph after forming carbon nanocrystals in an insulating film according to some embodiments of the invention. It can be seen from FIG. 12B that the carbon ions injected in the insulating film develop into a plurality of separate dots of nanocrystals 130.

FIG. 12C is an enlarged TEM photograph of the carbon nanocrystals of FIG. 12B. The regularly repeated diagonal lines in the carbon nanocrystal 130 in FIG. 12C indicate that the carbon nanocrystal is a generally good crystal.

FIG. 13 is a TEM photograph showing the cross-section of a nonvolatile memory device manufactured according to some embodiments of the invention. In FIG. 13, a plurality of carbon nanocrystals 130 is embedded in a film of SiO₂ substantially in a single layer. Further, it can be seen from FIGS. 12C and 13 that the carbon nanocrystals 130 are formed to have a diameter of about 4 nm.

FIG. 14 is a graph that shows a capacitance (C)-to-voltage (V) curve for a nonvolatile memory device, such as a nonvolatile memory device with a charge-trap structure including carbon nanocrystals according to some embodiments of the invention. It can be seen from the C-V curve that the nonvolatile memory device including carbon nanocrystals according to some embodiments of the invention has generally good counterclockwise hysteresis characteristics. Therefore, it can be seen that the nonvolatile memory device may be used as a memory element. Further, it can be seen from the flat band voltage shift of 8V that sufficient electrical charges can be stored.

The nonvolatile memory devices according to the embodiments described above of the invention are applicable to NAND-type nonvolatile memory devices or NOR-type nonvolatile memory devices. Further, they are applicable to stack-typed nonvolatile memory devices having two or more nonvolatile memory device layers. Each of the nonvolatile memory devices may be a NAND type or NOR type. In the embodiments described hereafter, the nonvolatile memory device is composed of layers of NAND type nonvolatile memory devices stacked in two layers, but other types are possible.

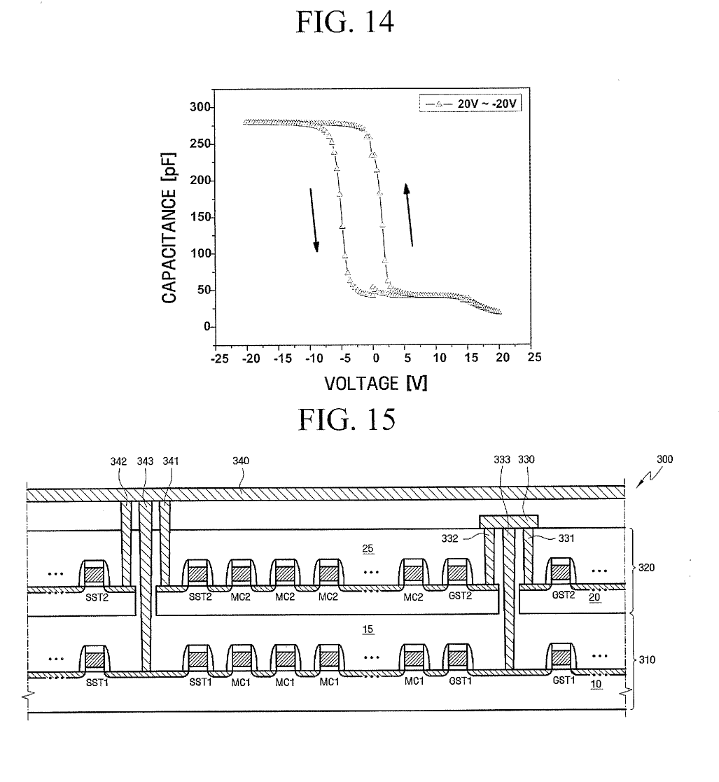

FIG. 15 is a cross-sectional view of a stack-typed nonvolatile memory device according to some embodiments of the invention. Transistors are schematically shown in FIG. 15.

Referring to FIG. 15, a stack-typed nonvolatile memory device 300, according to some embodiments of the invention, includes a first nonvolatile memory device layer 310 and a second nonvolatile memory device layer 320 stacked on the first nonvolatile memory device layer 310.

The first nonvolatile memory device layer 310 includes a plurality of first memory cell transistors MC1, first string selection transistors SST1, first grounding selection transistors GST1 that are formed on a first active region 10, and a first interlayer insulating film 15 covering the transistors MC1, SST1, and GST1. The first active region 10 provides a source/drain and channel for each of the transistors MC1, SST1, and GST1. The first active region 10 may be induced from the semiconductor substrate (i.e., a part of or the semiconductor substrate). The memory cell transistors MC1, string selection transistors SST1, and grounding selection transistors GST1 are connected in series and compose a string.

The second nonvolatile memory device layer 320 includes a plurality of second memory cell transistors MC2, second string selection transistors SST2, second grounding selection transistor GST2 that are formed on the second active region 20, and a second interlayer insulating film 25 covering the transistors MC2, SST2, and GST2. The second active region 20 provides a source/drain and channels for each of the transistors MC2, SST2, and GST2. The second active region 20 may be induced from the semiconductor substrate or the semiconductor layer (i.e., a part of or the semiconductor layer). When the second active region 20 is induced from the semiconductor substrate, the semiconductor substrate may be bonded to the first interlayer insulating film 15 of the first nonvolatile memory device layer 310. When the second active region 20 is induced from the semiconductor layer, the semiconductor layer is single-crystallized or multi-crystallized by annealing or laser treatment after epitaxy or vapor deposition on the first interlayer insulating film 15.

A bit line 340 and/or common source line 330 is formed on the second nonvolatile memory device layer 320. The bit line 340 is electrically connected with the second active region 20 of the second nonvolatile memory device layer 320 and/or the first active region 10 of the first nonvolatile memory device layer 310 through contacts 341, 342, and 343. The common source line 330 is electrically connected with the second active region 20 of the second nonvolatile memory device layer 320 and/or the first active region 10 of the first nonvolatile memory device layer 310 through contacts 331, 332, and 333.

The first memory cell transistor MC1 of the first nonvolatile memory device layer 310 and the first memory cell transistor MC2 of the second nonvolatile memory device layer 320 each include a charge-trap structure and store data. That is, the first memory cell transistor MC1 includes the first active region 10, a first charge-trap structure formed on the first active region 10, and a first gate formed on the first charge-trap structure. The second memory cell transistor MC2 includes the second active region 20, a second charge-trap structure formed on the second active region 20, and a second gate formed on the second charge-trap structure.

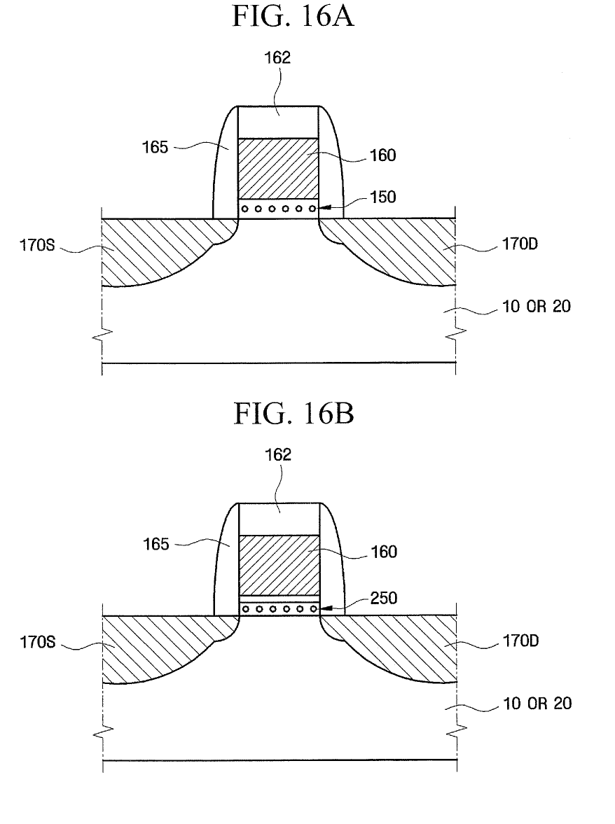

At least one of the first charge-trap structure and the second charge-trap structure may include a plurality of nanocrystals. Examples of the structure are shown in FIGS. 16A and 16B. FIG. 16A shows nanocrystals embedded in a single insulating film and FIG. 16B shows nanocrystals embedded in a multilayered insulating film including first and second insulating films. The embodiments shown in FIGS. 16A and 16B are substantially the same as the nonvolatile memory device embodiments discussed above and are not described in detail. In addition, it should be understood that all of the description of nonvolatile memory devices according to the above embodiments is applicable to the first charge-trap structure and/or the second charge-trap structure including nanocrystals.

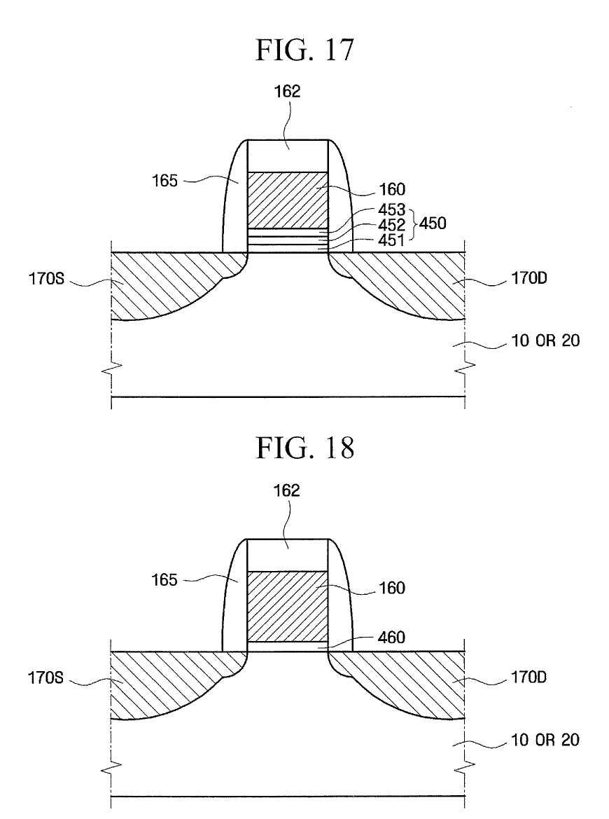

A configuration where at least one of the first charge-trap structure and the second charge-trap structure includes a plurality of nanocrystals includes not only when both first charge-trap structure and second charge-trap structure include a plurality of nanocrystals, but when one of the first charge-trap structure and the second charge-trap structure includes a plurality of nanocrystals, whereas the other does not include a plurality of nanocrystals. A memory cell transistor MC1 or MC2 when the first charge-trap structure or the second charge-trap structure does not include nanocrystals may have a transistor with the structure shown in FIG. 17. Referring to FIG. 17, a charge-trap structure 450 may include a tunneling layer 451, an electrical charge trap layer 452, and a blocking layer 453. For example, the tunneling layer 451 is formed of a silicon oxide film having a relatively high dielectric constant, the electrical charge trap layer 452, a silicon nitride film, and the blocking layer 453, a silicon oxide film or a film having high dielectric constant. However, the materials for the tunneling layer 451, electrical charge trap layer 452, and blocking layer 453 are not limited thereto, and the layers may be formed of other various materials known in the art in accordance with various embodiments of the invention.

The first string selection transistor SST1 and first grounding selection transistor GST1 of the first nonvolatile memory device layer 310, and the second string selection transistor SST2, and second grounding selection transistor GST2 of the second nonvolatile memory device layer 320, as shown in FIG. 18, each have a gate insulating film 460 instead of the charge-trap structure between the gate 160 and the active regions 10 or 20.

As described above, because the stack-typed nonvolatile memory device, according to some embodiments of the invention, has two or more stacked layers of memory components, it may have the advantage of relatively high integration. Further, because the charge-trap structures 150 and 250 including a plurality of nanocrystals shown in FIGS. 16A and 16B are smaller in thickness than the structure composed of the tunneling layer 451, electrical charge trap layer 452, and blocking layer 453 shown in FIG. 17, when at least one of the first charge-trap structure of the first memory cell transistor MC1 and the second charge-trap structure of the second memory cell transistor MC2 includes the nanocrystals, at least one of the first nonvolatile memory device layer 310 and the second nonvolatile memory device layer 320 may decrease in thickness. Therefore, when at least one of the first nonvolatile memory device layer 310 and the second nonvolatile memory device layer 320 decreases in thickness, the contacts 331 to 333 and 341 to 343 that connect the bit line 340 or the source 330 with the first active region 10 of the first nonvolatile memory device layer 310 and/or the second active region 20 of the second nonvolatile memory device layer 320 may decrease in height. When the contacts 331 to 333, 341 to 343 decrease in height, it may be easy to form the contacts 331 to 333 and 341 to 343, including forming and filling the contact holes. Moreover, the resistance of the contacts 331 to 333 and 341 to 343 may be reduced with an increase in physical and chemical stability.

According to methods of manufacturing a common nonvolatile memory device according to some embodiments of the present invention, the first nonvolatile memory device layer 310 is formed and the second nonvolatile memory device layer 320 is formed. According to the common manufacturing order, the first nonvolatile memory device layer 310 formed in advance is exposed to the following processes including, for example, manufacturing the second layer of the nonvolatile memory device 320. Accordingly, for example, the second layer of the nonvolatile memory device 320 is formed through a high-temperature process, and the first nonvolatile memory device layer 310 is correspondingly exposed to the high temperature, which may thereby reduce stability.

For example, when the first memory cell transistor MC1 of the first nonvolatile memory device layer 310 includes germanium nanocrystals and the second memory cell transistor MC2 of the second nonvolatile memory device layer 320 includes carbon nanocrystals, as described with reference to Table 1, annealing at about 1000° C. or more may be needed to form the carbon nanocrystals. However, as shown in Table 1, the melting point of germanium is about 940° C., so the germanium nanocrystals in the first memory cell transistor MC1 formed in advance may melt in annealing at the high temperature of about 1000° C. or more and the crystals may be broken. The germanium may re-crystallize depending on temperatures of following processes, but additional process management may be required and it may not be easy to re-crystallize the germanium into a pre-designed pattern.

Therefore, the first memory cell transistor MC1 of the second nonvolatile memory device layer 320 may be formed under process conditions that do not affect the stability of the lower first nonvolatile memory device layer 310.

For example, when the first memory cell transistor MC1 of the first nonvolatile memory device layer 310 is formed in the structure shown in FIG. 18, any one of the carbon nanocrystals, germanium nanocrystals, and silicon nanocrystals listed in Table 1 may be the nanocrystals included in the second memory cell transistor MC2 of the second nonvolatile memory device layer 320. However, the structure shown in FIG. 18 may have a problem at about 1050° C. or more, and the germanium nanocrystals that are formed at about 950° C. or less may be desirable for the nanocrystals used in the second layer of the nonvolatile memory device 320.

When the second memory cell transistor MC2 is formed in the structure shown in FIG. 18, a material for the nanocrystals of the first memory cell transistor MC1 may depend on the temperature to obtain the structure shown in FIG. 18. For example, when about 1050° C. or more is needed to achieve the structure of FIG. 18, carbon or silicon having a melting point above 1050° C. may be selected for the nanocrystals of the first memory cell transistor MC1.

When both of the first memory cell transistor MC1 and second memory cell transistor MC2 include nanocrystals, it may be desirable to set the melting point of the nanocrystals of the first memory cell transistor MC1 greater than the temperature for forming the nanocrystals of the second memory cell transistor MC2. For example, carbon nanocrystals having a 3547° C. melting point or silicon nanocrystals having a 1412° C. melting point may be applied to the first memory cell transistor MC1; materials in Table 1 that are applicable to the second memory cell transistor MC2 are carbon (nanocrystal-forming temperature: 1000 to 1250° C.), silicon (nanocrystal-forming temperature: 950 to 1100° C.), and germanium (nanocrystal-forming temperature: 700 to 950° C.). However, if germanium nanocrystals having a 940° C. melting point are applied to the first memory cell transistor MC1, it may be difficult to apply carbon nanocrystals or silicon nanocrystals having a higher nanocrystal-forming temperature than the melting point to the second memory cell transistor MC2. Therefore, it may be desirable to select the germanium crystals under the above conditions.

Although the present invention has been described in connection with the exemplary embodiments of the present invention, it will be apparent to those skilled in the art that various modifications and changes may be made thereto without departing from the scope and spirit of the invention. Therefore, it should be understood that the above embodiments are not limiting, but illustrative in all aspects.

According to a nonvolatile memory device and a method of manufacturing the same, according to some embodiments of the invention, it may be possible to achieve relatively good memory hysteresis characteristics with generally high reliability, and the combination with other processes may be relatively easy. Further, according to nonvolatile memory device embodiments of the invention, it may be possible to achieve generally high integration, improve the stability of contacts, and avoid or prevent significant reduction in stability of each layer of the memory devices in other processes.

That which is claimed:

1. A nonvolatile memory device, comprising:
a semiconductor substrate;
a charge-trap structure disposed on the semiconductor substrate, and comprising an insulating film and a plurality of carbon nanocrystals embedded in the insulating film; and
a gate disposed on the charge-trap structure.

2. The nonvolatile memory device of claim 1, wherein the carbon nanocrystals are spaced apart from the substrate and the gate.

3. The nonvolatile memory device of claim 2, wherein the insulating film comprises:
a first region between the semiconductor substrate and the carbon nanocrystals that functions as a tunneling insulating film; and
a second region between the gate and the carbon nanocrystals that functions as a coupling and blocking insulating film.

4. The nonvolatile memory device of claim 2, wherein the insulating film is about 30 nm or less in thickness.

5. The nonvolatile memory device of claim 2, wherein a distance between the semiconductor substrate and the carbon nanocrystals is about 9 nm or less.

6. The nonvolatile memory device of claim 2, wherein the insulating film is made of AₓO_{y}, AₓB₁₋ₓO_{y}, AₓO_{y}N_{z} or AₓB₁₋ₓO_{y}N_{z} (‘A’ and ‘B’ are different substances selected from a group consisting of Ti, Zr, Hf, Sc, Y, La and Al).

7. The nonvolatile memory device of claim 2, wherein the insulating film is a multilayered insulating film comprising a first insulating film and a second insulating film disposed on the first insulating film.

8. The nonvolatile memory device of claim 7, wherein:
the first insulating film is about 20 nm or less in thickness; and
the second insulating film is about 10 nm or less in thickness.

9. The nonvolatile memory device of claim 7, wherein the carbon nanocrystals are disposed in the first insulating film.

10. A method of manufacturing a nonvolatile memory device, comprising:
forming a charge-trap structure on a semiconductor substrate, the charge-trap structure comprising an insulating film and a plurality of carbon nanocrystals embedded in the insulating film; and
forming a gate on the charge-trap structure.

11. The method of claim 10, wherein forming the charge-trap structure comprises:
forming the insulating film on the semiconductor substrate;
injecting ions in the insulating film; and
annealing the insulating film to crystallize the ions and form carbon nanocrystals.

12. The method of claim 11, wherein the ions are injected at ion injection energy of about 30 to 80 KeV.

13. The method of claim 11, wherein the annealing is performed at a temperature between about 1000° C. and 1300° C.

14. The method of claim 11, further comprising:
annealing the insulating film before injecting the ions.

15. The method of claim 10, wherein the insulating film comprises a first insulating film and a second insulating film, and wherein forming the charge-trap structure comprises:
forming the first insulating film on the semiconductor substrate;
injecting ions into the first insulating film;
forming the second insulating film on the first insulating film; and
annealing the first insulating film to crystallize the ions and form carbon nanocrystals.

16. A stack-typed nonvolatile memory device, comprising:
a first nonvolatile memory device layer comprising a first active region, a first charge-trap structure disposed on the first active region, and a first gate disposed on the first charge-trap structure; and
a second nonvolatile memory device layer stacked on the first nonvolatile memory device layer and comprising a second active region, a second charge-trap structure disposed on the second active region, and a second gate disposed on the second nonvolatile memory device layer;
wherein at least one of the first charge-trap structure and the second charge-trap structure comprises an insulating film and a plurality of nanocrystals embedded in the insulating film.

17. The stack-typed nonvolatile memory device of claim 16, wherein:
the first charge-trap structure comprises a tunneling layer, an electrical trap layer, and a blocking layer; and
the second charge-trap structure comprises the insulating film and the nanocrystals embedded in the insulating film.

18. The stack-typed nonvolatile memory device of claim 17, wherein the nanocrystals are germanium nanocrystals.

19. The stack-typed nonvolatile memory device of claim 16, wherein;
the first charge-trap structure comprises the insulating film and the nanocrystals embedded in the insulating film; and
the second charge-trap structure comprises a tunneling layer, an electrical charge trap layer, and a blocking layer.

20. The stack-typed nonvolatile memory device of claim 19, wherein the nanocrystals are carbon nanocrystals and/or silicon nanocrystals.

21. The stack-typed nonvolatile memory device of claim 16, wherein the first charge-trap structure and the second charge-trap structure comprise first and second insulating films with first and second nanocrystals embedded therein, respectively.

22. The stack-typed nonvolatile memory device of claim 21, wherein the melting point of the first charge-trap structure is higher than the nanocrystal-forming temperature of the second nanocrystals of the second charge-trap structure.

23. The stack-typed nonvolatile memory device of claim 21, wherein:
the first nanocrystals of the first charge-trap structure are carbon nanocrystals and/or silicon nanocrystals; and
wherein the second nanocrystals of the second charge-trap structure are carbon nanocrystals, silicon nanocrystals, and/or germanium nanocrystals.

24. The stack-typed nonvolatile memory device of claim 21, wherein the first and second nanocrystals are germanium nanocrystals.
